(19) United States
(12) Patent Application Publication
(10) Pub. No.: US 2024/0128061 A1
(43) Pub. Date: Apr. 18, 2024

(54) APPARATUS DESIGN FOR FILM REMOVAL FROM THE BEVEL AND EDGE OF THE SUBSTRATE

(71) Applicant: Applied Materials, Inc., Santa Clara, CA (US)

(72) Inventors: FARZAD HOUSHMAND, Mountain View, CA (US); KELVIN CHAN, San Ramon, CA (US); RUIYING HAO, San Jose, CA (US); WAYNE FRENCH, San Jose, CA (US)

(21) Appl. No.: 18/233,760

(22) Filed: Aug. 14, 2023

Related U.S. Application Data
(60) Provisional application No. 63/415,808, filed on Oct. 13, 2022.

(51) Int. Cl. H01J 37/32

(52) U.S. Cl. CPC H01J 37/32715; H01J 37/32357; H01J 37/32449; H01J 2237/20214; H01J 2237/334

(57) ABSTRACT

Embodiments disclosed herein include a semiconductor processing tool. In an embodiment, the semiconductor processing tool comprises a pedestal, an annular separator over the pedestal to define a first domain within the annular separator and a second domain outside of the annular separator, a first gas inlet within the annular separator, and a second gas inlet outside of the annular separator.

### CROSS-REFERENCE TO RELATED APPLICATIONS

This application claims the benefit of U.S. Provisional Application No. 63/415,808, filed on Oct. 13, 2022, the entire contents of which are hereby incorporated by reference herein.

### BACKGROUND

### 1) Field

Embodiments relate to the field of semiconductor manufacturing and, in particular, to a processing tool that includes a dual domain setup to selectively etch the bevel and edge of a substrate.

### 2) Description of Related Art

In semiconductor manufacturing, layers or films are often deposited over a surface of a substrate, such as a semiconductor wafer. The layer or film is deposited over an entire top surface of the substrate, and may also deposit along sidewall surfaces of the substrate. For easier material handling, the edge and bevel of the substrate may need to be etched in order to expose the bare substrate material or the underlying material. For example, a ring with approximately 1 mm thickness may be desired around the outer perimeter of the substrate. The etching process used to form the ring may include the use of masks and the like. Alternatively, a shadow ring may be provided over the substrate during the deposition process in order to prevent deposition of the layer around the outer perimeter.

### SUMMARY

Embodiments disclosed herein include a semiconductor processing tool. In an embodiment, the semiconductor processing tool comprises a pedestal, an annular separator over the pedestal to define a first domain within the annular separator and a second domain outside of the annular separator, a first gas inlet within the annular separator, and a second gas inlet outside of the annular separator.

Embodiments may further include a method of etching an edge and a bevel of a substrate. In an embodiment, the method comprises providing a substrate in a chamber, where a layer is on a surface of the substrate, and where the chamber includes an annular separator that separates a first domain over a center of the substrate from a second domain over a perimeter of the substrate. In an embodiment, the method may further comprise flowing a first gas into the first domain, and flowing a second gas into the second domain, where the second gas etches the layer on the edge of the substrate.

Embodiments may further comprise a semiconductor processing tool that comprises a chamber, a pedestal in the chamber, where the pedestal is vertically displaceable, and an annular separator in the chamber above the pedestal, where the annular separator defines a first domain above a center of the pedestal and a second domain around a perimeter of the pedestal. In an embodiment, the tool further comprises a showerhead configured to flow a first gas into the first domain, and a gas inlet configured to flow a second gas into the second domain, where the first gas and the second gas do not mix until after the first gas flows through a gap between the first domain and the second domain.

### BRIEF DESCRIPTION OF THE DRAWINGS

FIG. 1A is a plan view illustration of a substrate with a layer deposited on the substrate with a bare ring around a perimeter of the substrate, in accordance with an embodiment.

FIG. 1B is a cross-sectional illustration of the substrate with a layer and a bare ring around a perimeter of the substrate, in accordance with an embodiment.

FIG. 2 is a cross-sectional illustration of a semiconductor processing tool that includes an annular separator in order to separate the chamber volume into a first domain and a second domain, in accordance with an embodiment.

FIG. 3 is a cross-sectional illustration of a portion of the semiconductor processing tool that zooms in on the annular separator that separates the first domain form the second domain, in accordance with an embodiment.

FIG. 4A is a plan view illustration of a portion of a semiconductor processing tool that includes an annular separator between a first domain and a second domain, where the gas flow in the second domain surrounds the perimeter of the first domain, in accordance with an embodiment.

FIG. 4B is a plan view illustration of a portion of a semiconductor processing tool that includes an annular separator between a first domain and a second domain, where the gas flow in the second domain is localized and the pedestal is rotated, in accordance with an embodiment.

FIG. 4C is a plan view illustration of a portion of a semiconductor processing tool that includes an annular separator between a first domain and a second domain, where the gas flow in the second domain is localized to a pair of sites, and the pedestal is rotated, in accordance with an embodiment.

FIG. 5 is a process flow diagram depicting a process for etching an edge and bevel of a substrate in a semiconductor processing tool that includes an annular separator, in accordance with an embodiment.

FIG. 6 illustrates a block diagram of an exemplary computer system that may be used in conjunction with a processing tool, in accordance with an embodiment.

### DETAILED DESCRIPTION

Systems described herein include a processing tool that includes a dual domain setup to selectively etch the bevel and edge of a substrate. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, it is often desirable to include a layer over a substrate that includes a bare edge and bevel. As used herein, the edge of a substrate refers to a ring on the top surface of the substrate that extends a distance into the center of the substrate. For example, an edge with a thickness of approximately 1.0 mm may be provided around an outer perimeter of a substrate. The bevel may refer to the sidewall surface of the substrate. The bevel may be vertical in some embodiments, or the bevel may have a rounded surface or the like.

A layer or film may be provided on the substrate within the outer edge. Additionally, the bevel and edge of the substrate may be free from the layer or film. The inclusion of a bare edge of the substrate may be necessary for subsequent processing, handling, or the like. Generally, the layer or film is blanket deposited over the entire surface of the substrate, and is subsequently etched away at the edge locations, The etching process can be time consuming and adds an additional step into the process flow. As such, it is desirable to omit such additional processes.

Accordingly, embodiments disclosed herein include a semiconductor processing tool that includes an annular separator that can be used to selectively etch the edge and bevel of the substrate. Generally speaking, the annular separator divides the processing volume into a first domain and a second domain around the first domain. The first domain is supplied with an inert gas that does not damage the layer on the substrate, and the second domain is supplied with an etchant species (e.g., through thermal etching or plasma-assisted etching) that will selectively etch the layer around the outer perimeter and edge of the substrate. In an embodiment, the pedestal is displaceable so that a small gap exists between the bottom of the annular separator and the top surface of the substrate. Due to the small height of the gap and pressure difference between the first domain and the second domain, the inert gas flows into the second domain. The flow of the inert gas prevents the backflow of the etchant species into the first domain. As such, the edge and bevel of the substrate can be selectively etched without damaging the remainder of the film.

In a particular embodiment, the etchant gas (or effluent from an etchant plasma) is flown into the entirety of the second domain. That is, the etchant species flows around an entire perimeter of the substrate. In such embodiments, the pedestal may be stationary. In other embodiments, the etchant gas (or effluent from an etchant plasma) is delivered to a single point (or multiple points) around a perimeter of the substrate. In order to allow for uniform etching of the entire substrate, the pedestal on which the substrate is supported may be rotated.

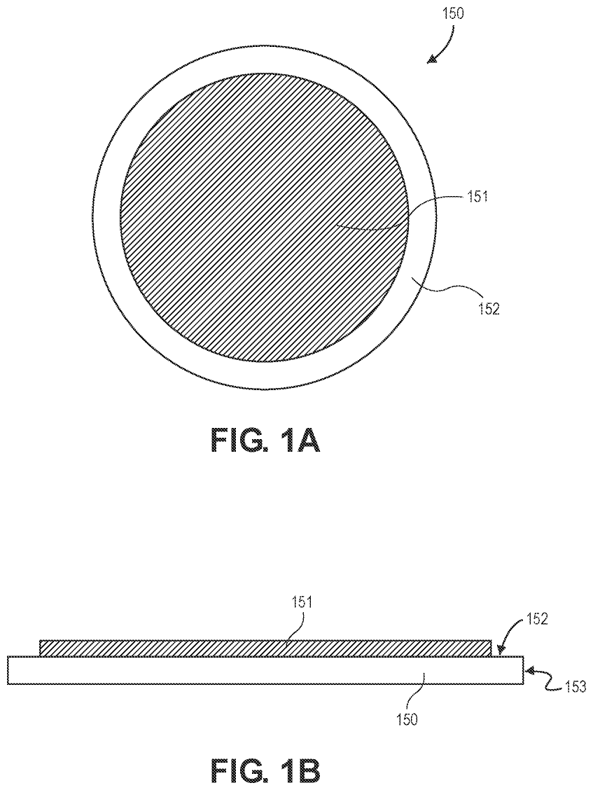

Referring now to FIG. 1A, a plan view illustration of a substrate 150 is shown, in accordance with an embodiment. In an embodiment, the substrate 150 may be a semiconductor substrate, such as a semiconductor wafer. For example, the substrate 150 may be a silicon wafer. The substrate 150 may have a typical wafer form factor (e.g., 150 mm, 300 mm, 450 mm, etc.). Though, it is to be appreciated that other form factors may be used in some embodiments. For example, the substrate 150 need not be round or circular in some instances.

In an embodiment, the substrate 150 may have a layer 151 provided on a top surface of the substrate 150. The layer 151 may be deposited on the substrate 150 using any suitable material deposition process (e.g., chemical vapor deposition (CVD), physical vapor deposition (PVD), atomic layer deposition (ALD), or the like). As shown, the layer 151 is isolated to a center of the substrate 150. That is, a bare ring 152 may be provided around a perimeter of the layer 151. The bare ring 152 may expose the top surface of the substrate 150. The bare ring 152 may have a width that is up to approximately 5.0 mm. In a particular embodiment, the width of the bare ring 152 may be approximately 1.0 mm or less, or even approximately 0.1 mm or less. As used herein, “approximately” may refer to a range of values that are within ten percent of the stated value. For example, approximately 1.0 mm may refer to a range between 0.9 mm and 1.1 mm. The bare ring 152 may be used for improving substrate 150 handling and/or for the benefit of subsequent processing operations on the substrate 150.

Referring now to FIG. 1B, a cross-sectional illustration of the substrate 150 is shown, in accordance with an embodiment. As shown, the layer 151 is provided over a top surface of the substrate 150. The layer 151 may have any suitable thickness. For example, the layer 151 may range from several nanometers thick to hundreds of microns thick. In an embodiment, the layer 151 may be isolated to the center of the substrate 150. That is, a bare ring 152 may surround an outer perimeter of the layer 151. Also, the bevel 153 of the substrate 150 may be free from the layer 151.

In an embodiment, the layer 151 may be any material or materials suitable for semiconductor manufacturing processes. The layer 151 may be used as part of a transistor device, a microelectromechanical system (MEMS), or any other structure fabricated with a semiconductor processing tool. In a particular embodiment, the layer 151 may comprise tin and one or more other material constituents. For example, the layer 151 may comprise tin oxide (SnO), tin nitride (SnN), tin carbide (SnC), tin oxycarbide (SnOC), tin oxynitride (SnON), tin carbonitride (SnCN), tin oxycarbonitride (SnOCN), and the like. In some instances the layer 151 may further comprise hydrogen. While particular examples of some films are provided herein, it is to be appreciated that any film that can be etched with a thermal etching process or a plasma-assisted etching process may be used in embodiments described herein.

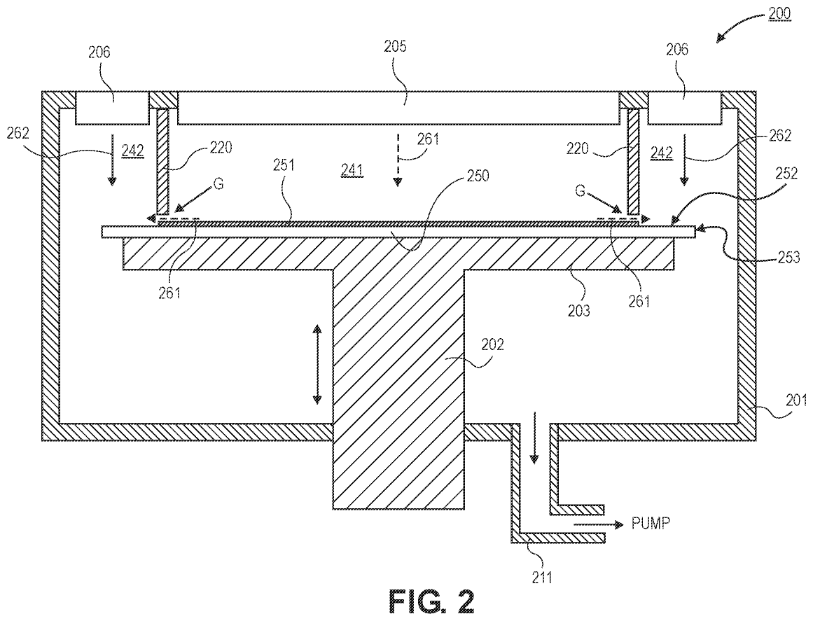

Referring now to FIG. 2, a cross-sectional illustration of a semiconductor processing tool 200 is shown, in accordance with an embodiment. In an embodiment, the semiconductor processing tool 200 may comprise a chamber 201. The chamber 201 may be suitable for maintaining low pressure environments, such as pressures suitable for striking and maintaining a plasma. In an embodiment, an exhaust 211 may be provided that fluidically couples with a pump (not shown). The pump may enable the low pressure environment and aid in the removal of etch byproducts and other species from the chamber 201.

In an embodiment, the semiconductor processing tool 200 may comprise a pedestal 202. A chuck 203 may be provided on the pedestal 202. In an embodiment, the chuck 203 may be an electrostatic chuck (ESC) or the like. The chuck 203 may include heating and/or cooling solutions in order to control a temperature of the substrate 250 that is secured by the chuck 203. In an embodiment, the pedestal 202 may be configured to displace vertically, as indicated by the double sided arrow adjacent to the pedestal 202. In some embodiments, the pedestal 202 is displaced vertically until the substrate is spaced away from the annular separator 220 by a gap G. For example, the gap G may be approximately 5 mm or less, or approximately 1 mm or less.

When positioned with a gap G between the substrate 250 and the annular separator 220, the semiconductor processing tool 200 may be in a configuration suitable for edge and bevel etching, as will be described in greater detail below. When the substrate 250 is further from the annular separator 220, a deposition process (e.g., to deposit layer 251) may be executed. That is, in some embodiments, both deposition and edge etching can be accomplished in a single chamber 201. In other embodiments, the semiconductor processing tool 200 may be dedicated for edge and bevel etching. That is, the deposition of the layer 251 may occur in a different processing chamber.

In an embodiment, the substrate 250 may have a diameter that is greater than the diameter of the chuck 203. That is, an edge 252 of the substrate and the bevel 253 may be outside of the chuck 203. In an embodiment, the substrate 250 may have any form factor, such as the form factors described above. Additionally, the layer 251 on the substrate 250 may be any suitable layer for semiconductor processing, such as those described in greater detail above. In the illustrated embodiment, the substrate 250 is shown after an etching process that removes the layer 251 from the edge 252 and the bevel 253.

In an embodiment, the annular separator 220 may be provided on a lid or top surface of the chamber 201. The annular separator 220 may be a physical structure that separates a first domain 241 of the chamber 201 from a second domain 242 of the chamber 201. The annular separator 220 may be a ring in some embodiments. The first domain 241 may be provided over a center of the substrate 250, and the second domain 242 may be an outer ring of space that is provided over the edge 252 of the substrate 250. The annular separator 220 may be provided at the edge of the layer 251. Accordingly, the layer 251 may be provided in the first domain 241, and the bare edge 252 and bevel 253 may be provided in the second domain 242.

In an embodiment, a first gas inlet 205 may be provided in the first domain 241. The first gas inlet 205 may be a showerhead or the like. In a particular embodiment, the first gas inlet 205 may supply a first gas 261 into the first domain 241. The first gas 261 may be an inert gas in some embodiments. For example, the first gas may comprise argon and/or nitrogen. The first gas 261 may flow out of the first domain 241 through the gap G into the second domain 242. In an embodiment, a second gas inlet 206 may be provided in the second domain 242. The second gas inlet 206 may be a showerhead or the like. Additionally, the second gas inlet 206 may provide a localized flow of a second gas 262, or the second gas 262 may be distributed throughout the entire second domain 242.

In FIG. 2, the first gas inlet 205 and the second gas inlet 206 are described as flowing gas into the chamber 201. The gas may then be fed into a plasma in some embodiments. Alternatively one or more remote plasma sources may be used to provide a plasma into the first domain 241 and/or the second domain 242.

In an embodiment, the second gas 262 may be a processing gas that allows for etching of the layer 251. For example, the second gas 262 may comprise one or more of HCl, HBr, HI, and SOCl₂. In the case of a thermal etch, the second gas 262 provides the necessary chemical reaction to remove the layer 251 from the edge 252 and the bevel 253. In embodiments that include a plasma, atomic H, Cl, Br, and/or I can provide the necessary chemical reaction to remove the layer 251. In yet another embodiment, the etching chemistry may include both the first gas 261 and the second gas 262. For example, hydrogen or a hydrocarbon may be part of the first gas 261. As the first gas 261 passes through the gap G, the reactive portion of the first gas 261 may react with the second gas 262 in order to provide an etching chemistry. For example, when H₂ meets Cl near the edge 252, Cl+H₂→HCl+H. That is, the species H, Cl, and HCl may all be present simultaneously as etchants. Similarly, when the first gas comprises a hydrocarbon (e.g., C_{X}H_{Y}), H⁻ from the second gas 261 can react with the hydrocarbon of the first gas 261 to form etchants such as C₃H₇, CH₃, and C₂H₅.

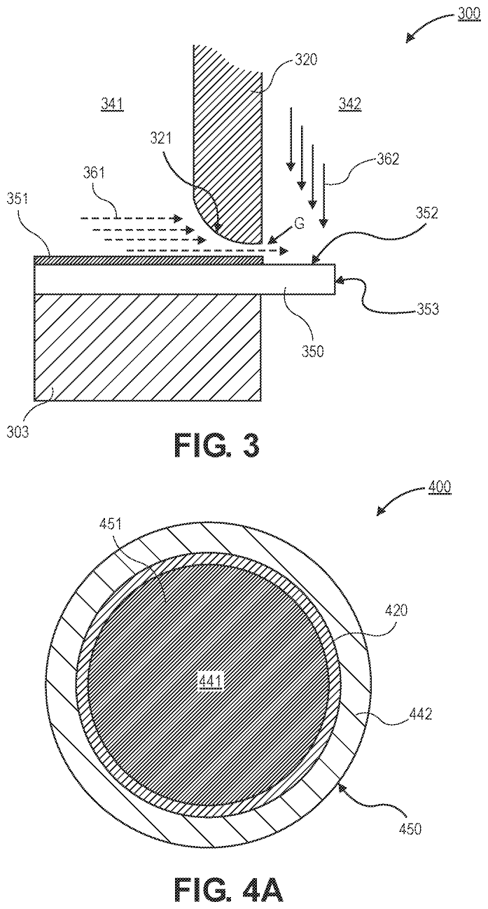

Referring now to FIG. 3, a cross-sectional illustration of a portion of a semiconductor processing tool 300 is shown, in accordance with an embodiment. In the illustration of FIG. 3, the interface between the annular separator 320 and the substrate 350 is shown, in accordance with an embodiment. As shown, the annular separator 320 separates the first domain 341 (left side of the annular separator 320) from the second domain 342 (right side of the annular separator 320).

In an embodiment, the substrate 350 may be provided on the chuck 303. The substrate 350 may be any form factor substrate, such as those described in greater detail above. In an embodiment, the substrate 350 may have a layer 351 formed on a top surface of the substrate 350. The layer 351 may be any material used for semiconductor manufacturing, such as those described in greater detail above. In an embodiment, the layer 351 may be located in the center of the substrate 350. That is, an edge 352 and a bevel 353 of the substrate 350 may be free from the layer 351. For example, an etching process in the chamber 300 may be used to remove the layer 351 from the edge 352 and the bevel 353. In an embodiment, the edge 352 may have any suitable width. For example, the edge 352 may have a width up to approximately 5 mm, up to approximately 1 mm, or up to approximately 0.1 mm.

In an embodiment, the annular separator 320 may be a physical structure. For example, the annular separator 320 may comprise a ceramic material that is resistant to etching chemistry used to form the bare edge 352 and bevel 353. In an embodiment, a bottom surface 421 of the annular separator 320 may be curved. The curved bottom surface 421 may be oriented so as to improve flow of a first gas 361 in the first domain 341 through the gap G into the second domain 342.

In an embodiment, the pressure in the first domain 341 may be greater than a pressure in the second domain 342. As such, the first gas 361 flows through the gap G and prevents the backflow of the second gas 362 into the first domain 341. Since the second gas 362 is the etchant species (or reacts with the first gas to form the etchant species), no etching will occur under the annular separator 320 or within the annular separator 320 in the first domain 341. However, etching will occur in the second domain 342 to form a bare edge 352 and a bare bevel 353. In an embodiment, the first gas 361 and the second gas 362 may be separated from each other until they reach each other after the first gas 361 passes through the gap G.

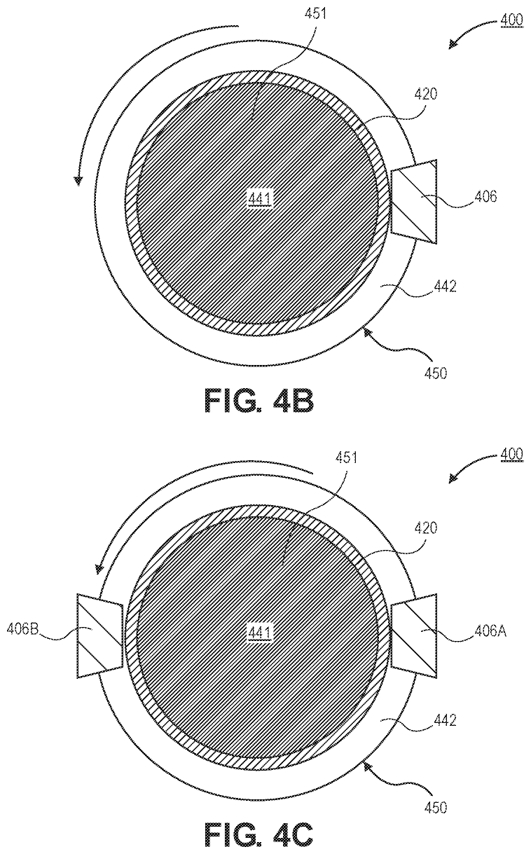

Referring now to FIGS. 4A-4C, a series of plan view illustrations of a portion of a semiconductor processing tool 400 is shown, in accordance with various embodiments. In FIG. 4A, the second domain is uniformly filled with an etchant gas or species from a plasma. In FIG. 4B, the second domain has the gas or effluent from a plasma injected at a single point, and the substrate is rotated. Similarly, in FIG. 4C, a pair of injection points are used and the substrate is rotated.

Referring now to FIG. 4A, a plan view illustration of a portion of a semiconductor processing tool 400 is shown, in accordance with an embodiment. In an embodiment, a substrate 450 may be provided below an annular separator 420. Within the annular separator 420, a layer may be provided in the first domain 441 over the substrate 450. A first gas (not shown) may be flown into the interior of the annular separator 420 in the first domain 441, similar to embodiments described in greater detail above. In an embodiment, a second gas or effluent from a plasma is flown into the second domain 442 in the region around the annular separator 420. For example, a gas distribution plate (e.g., showerhead) or the like may be used to uniformly dispense the second gas or effluent from a plasma over the outer edge and bevel of the substrate 450 in the second domain 442. As such, regions of the substrate 450 outside of the annular separator 420 will not have the layer.

Referring now to FIG. 4B, a plan view illustration of a portion of a semiconductor processing tool 400 is shown, in accordance with an embodiment. In an embodiment, the semiconductor processing tool 400 in FIG. 4B may be substantially similar to the semiconductor processing tool 400 in FIG. 4A, with the exception of the flow of the second gas or effluent from a plasma in the second domain 442. Instead of being uniformly distributed throughout the second domain 442, a single injection site 406 may be used. In such embodiments, the totality of the edge and bevel may be etched by rotating the substrate 450, as shown by the arrow. The rotation results in all portions of the edge and the bevel being brought under the injection site 406 in order to be etched.

Referring now to FIG. 4C, a cross-sectional illustration of a portion of a semiconductor processing tool 400 is shown, in accordance with an embodiment. In an embodiment, the semiconductor processing tool 400 in FIG. 4C may be substantially similar to the semiconductor processing tool 400 in FIG. 4B, with the exception of the number of injection sites 406. For example, a pair of injection sites 406A and 406B may be provided on opposite ends of the substrate 450. Similar to the embodiment in FIG. 4B, the substrate 450 may be rotated (e.g., with a rotating pedestal) in order to uniformly etch the entire edge and bevel.

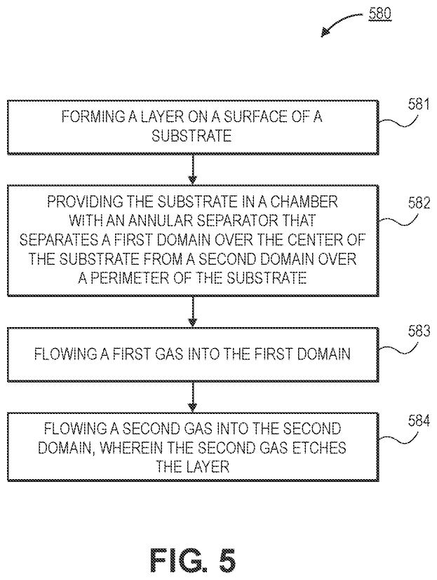

Referring now to FIG. 5, a process flow diagram of a process 580 for etching a layer from the edge and bevel of a substrate is shown, in accordance with an embodiment. In an embodiment, the process 580 may be executed in a semiconductor processing tool similar to any of the embodiments described herein. For example, the semiconductor processing tool may include an annular separator in order to separate a first domain from a second domain. The etching chemistry may be provided in the second domain, and the second domain may be over the edge and bevel of the substrate.

In an embodiment, the process 580 may begin with operation 581, which comprises forming a layer on a surface of a substrate. In an embodiment, the layer may be formed with a blanket deposition process. As such, an entire top surface of the substrate may be coated by the layer. The layer may also be provided over the bevel of the substrate in some embodiments. In an embodiment, the layer may be any layer suitable for semiconductor manufacturing processes. In a particular embodiment, the layer may comprise one or more of tin oxide (SnO), tin nitride (SnN), tin carbide (SnC), tin oxycarbide (SnOC), tin oxynitride (SnON), tin carbonitride (SnCN), tin oxycarbonitride (SnOCN), and the like. The layer may further comprise hydrogen in some embodiments. In an embodiment, the substrate may be a silicon wafer, though other materials and form factors may also be used for the substrate.

In an embodiment, the process 580 may continue with operation 582, which comprises providing the substrate in a chamber with an annular separator that separates a first domain over a center of the substrate from a second domain over a perimeter of the substrate. The second domain may be over the region of the substrate where a bare edge and a bare bevel is desired. For example, the outer surface of the annular separator may be set in from the outer most edge of the substrate by up to approximately 5 mm, or up to approximately 1 mm. In an embodiment, the chamber with the annular separator may be a different chamber than the chamber used to deposit the layer on the substrate. In other embodiments, the chamber with the annular separator may be the same chamber used to deposit the layer on the substrate.

The annular separator may be similar to any of the annular separator embodiments described in greater detail above. For example, the annular separator may be a physical structure that extends down from a lid of the chamber. The bottom of the annular separator may be spaced away from the substrate by a gap G. The gap G may be greater than a thickness of the layer, so that there is a path that can fluidically couple to the first domain to the second domain.

In an embodiment, process 580 may continue with operation 583, which comprises flowing a first gas into the first domain. In an embodiment, the first gas may be an inert gas, such as argon or nitrogen. Though, as will be described in greater detail below, a constituent of the etching reaction may also be part of the first gas. For example, hydrogen and/or hydrocarbons (which by themselves do not etch the layer) may be part of the first gas.

In an embodiment, process 580 may continue with operation 584, which comprises flowing a second gas into the second domain. In an embodiment, operations 583 and 584 may occur at the same time. That is, both the first gas and the second gas may be flown into the chamber at the same time. In an embodiment, the second gas etches the layer. In an embodiment, the second gas may include one or more of HCl, HBr, HI, and SOCl₂. In one embodiment, the second gas is used to etch the layer. For example, a thermal etching process may be used. In other embodiments, the second gas may be fed into a plasma, and the effluent species from the plasma contribute to the etching of the layer. While operation 584 includes flowing a second gas into the second domain, it is also possible to flow a plasma effluent into the second domain. That is, a remote plasma source may be used to provide a plasma effluent to the second domain in some embodiments.

In an embodiment, the second gas (or plasma effluent) is prevented from flowing into the first domain. As such, the layer at the center of the substrate is protected from etching. The second gas is prevented from flowing into the first domain by the flow of the first gas. For example, a pressure in the first domain may be greater than a pressure in the second domain, so that the first gas flows out and prevents back diffusion of the second gas.

In an additional embodiment, the flow of the first gas into the second domain can also be used to initiate the etching process. For example, the first gas may further comprise hydrogen. When the hydrogen enters the second domain, the hydrogen may react with atomic halogens to form the etching chemistry. For example, in the case of a Cl halogen, Cl+H₂→HCl+H. That is, the species H, Cl, and HCl may all be present simultaneously as etchants. Similarly, when the first gas comprises a hydrocarbon (e.g., C_{X}H_{Y}), H from the second gas can react with the hydrocarbon of the first gas to form etchants such as C₃H₇, CH₃, and C₂H₅.

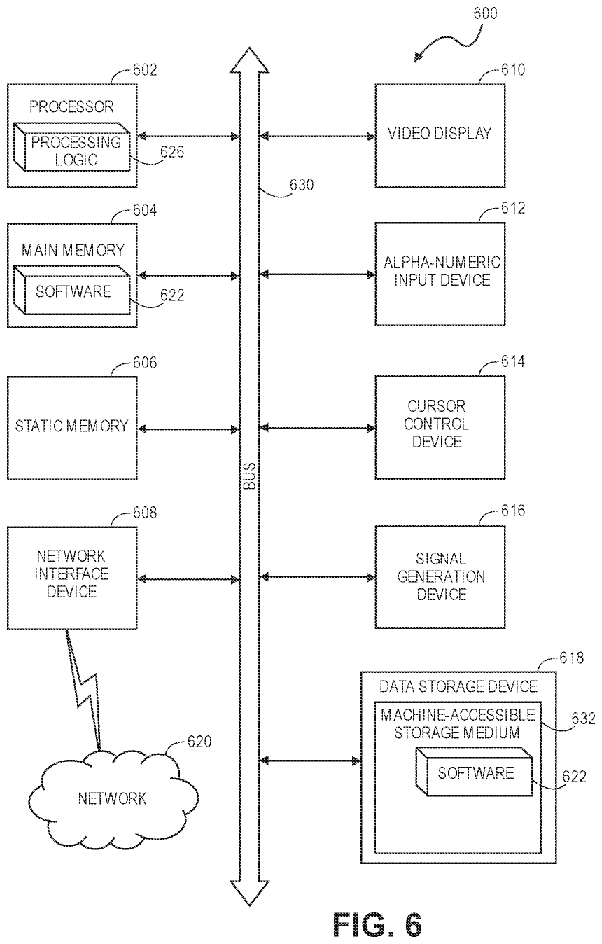

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 632 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 620 via the system network interface device 608. In an embodiment, the network interface device 608 may operate using RF coupling, optical coupling, acoustic coupling, or inductive coupling.

While the machine-accessible storage medium 632 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A semiconductor processing tool, comprising:
a pedestal;
an annular separator over the pedestal to define a first domain within the annular separator and a second domain outside of the annular separator;
a first gas inlet within the annular separator; and
a second gas inlet outside of the annular separator.

2. The semiconductor processing tool of claim 1, wherein the pedestal is configured to be displaced relative to the annular separator.

3. The semiconductor processing tool of claim 2, wherein a bottom of the annular separator is up to 10 mm above the pedestal.

4. The semiconductor processing tool of claim 1, wherein a bottom surface of the annular separator is curved.

5. The semiconductor processing tool of claim 1, wherein the second gas inlet is configured to spread gasses around a perimeter of the annular separator.

6. The semiconductor processing tool of claim 1, wherein the second gas inlet is configured to dispense gas in a portion of the second domain.

7. The semiconductor processing tool of claim 6, wherein the pedestal rotates.

8. The semiconductor processing tool of claim 1, wherein the first gas inlet supplies an inert gas into the first domain, and wherein the second gas inlet supplies an etchant gas into the second domain.

9. The semiconductor processing tool of claim 8, wherein the inert gas is configured to flow from the first domain to the second domain through a gap between the annular separator and the pedestal.

10. The semiconductor processing tool of claim 1, wherein the second domain is configured to support formation of a plasma.

11. The semiconductor processing tool of claim 1, further comprising:
a substrate on the pedestal, wherein the annular separator is above a boundary between an inner region of the substrate and an outer region of the substrate, wherein the inner region is covered by a layer, and wherein the outer region is bare.

12. A method of etching an edge and a bevel of a substrate, comprising:
providing a substrate in a chamber, wherein a layer is on a surface of the substrate, and wherein the chamber includes an annular separator that separates a first domain over a center of the substrate from a second domain over a perimeter of the substrate;
flowing a first gas into the first domain; and
flowing a second gas into the second domain, wherein the second gas etches the layer on the edge of the substrate.

13. The method of claim 12, wherein the second gas is fed into a plasma.

14. The method of claim 13, wherein the plasma is a remote plasma whose effluent flows into the second domain.

15. The method of claim 12, wherein etching the layer is a thermal process.

16. The method of claim 12, wherein the first gas flows into the second domain at a gap between the annular separator and the substrate.

17. The method of claim 16, wherein the first gas reacts with the second gas to form an etchant.

18. A semiconductor processing tool, comprising:
a chamber;
a pedestal in the chamber, wherein the pedestal is vertically displaceable;
an annular separator in the chamber above the pedestal, wherein the annular separator defines a first domain above a center of the pedestal and a second domain around a perimeter of the pedestal;
a showerhead configured to flow a first gas into the first domain; and
a gas inlet configured to flow a second gas into the second domain, wherein the first gas and the second gas do not mix until after the first gas flows through a gap between the first domain and the second domain.

19. The semiconductor processing tool of claim 18, wherein the semiconductor processing tool comprises a remote plasma source.

20. The semiconductor processing tool of claim 18, wherein the pedestal rotates.
